(19) United States
(12) Patent Application Publication
(10) Pub. No.: US 2022/0262657 A1
(43) Pub. Date: Aug. 18, 2022

(54) PEDESTAL WITH MULTI-ZONE HEATING

(71) Applicant: Applied Materials, Inc., Santa Clara, CA (US)

(72) Inventors: Rohit MAHAKALI, Bangalore (IN); Wenfei ZHANG, San Jose, CA (US); Chaitanya Anjaneyalu PRASAD, Cupertino, CA (US)

(21) Appl. No.: 17/630,492

(22) PCT Filed: Jun. 30, 2020
(86) PCT No.: PCT/US2020/040220

§ 371 Date: Jan. 26, 2022

(30) Foreign Application Priority Data
Aug. 2, 2019 (IN) 201941031268

(51) Int. Cl. H01L 21/67; H01L 21/687

(52) U.S. Cl. CPC H01L 21/67103; H01L 21/68785; H01L 21/67109

(57) ABSTRACT

A method and apparatus for improved temperature control of a substrate is disclosed. In one embodiment, a pedestal is disclosed that includes a top plate, and a base plate coupled to the top plate, wherein the top plate comprises a multi-zone heater and the base plate comprises a plurality of grooves formed in a bottom surface thereof.

### BACKGROUND

### Field

Embodiments of the present disclosure generally relate to semiconductor processing equipment. More particularly, embodiments of the present disclosure relate to a chemical vapor deposition (CVD) chamber and pedestal for semiconductor fabrication and in situ dry cleaning methods using the same.

### Description of the Related Art

In the fabrication of electronic devices on semiconductor substrates, a substrate is positioned on a heated pedestal configured to control the temperature of the substrate. However, with conventional pedestals, uniform heating of the substrate is often difficult to realize. For example, during etch processes; non-uniformities are typically present in the substrate caused by “edge roll-off” and/or “skew”. These non-uniformities are caused, at least in part, by temperature non-uniformities in the substrate during the etch process. In addition, conventional pedestals tend to lower throughput due to slow temperature ramp-up and/or slow transient temperatures.

There is a need, therefore, for a pedestal capable of improved temperature control of a substrate positioned thereon.

### SUMMARY

A method and apparatus for improved temperature control of a substrate is disclosed. In one embodiment, a pedestal is disclosed that includes a top plate, and a base plate coupled to the top plate, wherein the top plate comprises a multi-zone heater and the base plate comprises a plurality of grooves formed in a bottom surface thereof.

In another embodiment, a pedestal is disclosed that includes a top plate, a base plate coupled to the top plate, and a cooling plate coupled to the base plate, wherein the top plate comprises a four zone heater and the base plate comprises a plurality of grooves formed in a surface that is in contact with the cooling base.

In another embodiment, a pedestal is disclosed that includes a top plate, a base plate coupled to the top plate, and a cooling plate coupled to the base plate, wherein the top plate comprises a four heating zones and the base plate comprises a plurality of grooves formed in a surface that is in contact with the cooling base, and wherein a thermal break is positioned between adjacent heating zones.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial cross sectional view showing an illustrative processing chamber.

FIG. 2 shows a partial cross sectional view of an illustrative pedestal in a portion of the processing chamber

FIG. 3 is an isometric top view of a pedestal as disclosed herein.

FIGS. 4A and 4B are isometric sectional views of the pedestal of FIG. 3.

FIG. 5 is a schematic view of a bottom surface of the support member of the pedestal of FIG. 3.

FIG. 6 is a partial sectional view of the pedestal with a portion of a substrate positioned thereon.

FIG. 7 is a bottom perspective view of the pedestal showing another embodiment of the base plate.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

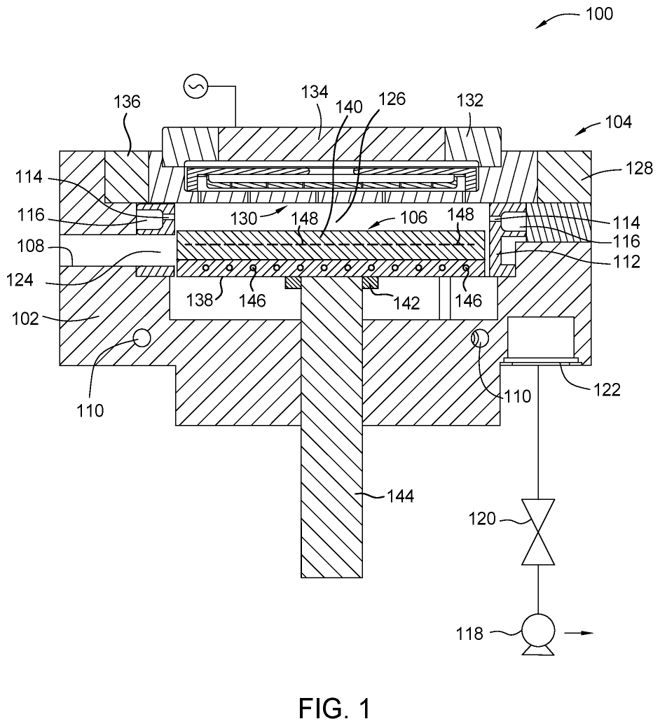

FIG. 1 is a partial cross sectional view showing an illustrative processing chamber 100. In one embodiment, the processing chamber 100 includes a chamber body 102, a lid assembly 104, and a support assembly or pedestal 106. The lid assembly 104 is disposed at an upper end of the chamber body 102, and the pedestal 106 is at least partially disposed within the chamber body 102. The processing chamber 100 and the associated hardware are preferably formed from one or more process-compatible materials, such as aluminum.

The chamber body 102 includes a slit valve opening 108 formed in a sidewall thereof to provide access to the interior of the processing chamber 100. The slit valve opening 108 is selectively opened and closed to allow access to the interior of the chamber body 102 by a handling robot (not shown). In one embodiment, a substrate can be transported in and out of the processing chamber 100 through the slit valve opening 108 to an adjacent transfer chamber and/or load-lock chamber, or another chamber within a cluster tool.

In one or more embodiments, the chamber body 102 includes a channel 110 formed therein for flowing a heat transfer fluid therethrough. The heat transfer fluid can be a heating fluid or a coolant and is used to control the temperature of the chamber body 102 during processing and substrate transfer. The temperature of the chamber body 102 is important to prevent unwanted condensation of the gas or byproducts on the chamber walls. Exemplary heat transfer fluids include water, ethylene glycol, or a mixture thereof. An exemplary heat transfer fluid may also include nitrogen gas.

The chamber body 102 also includes a liner 112 that surrounds the pedestal 106. The liner 112 is preferably removable for servicing and cleaning. The liner 112 can be made of a metal such as aluminum, or a ceramic material. However, the liner 112 can be any process compatible material. The liner 112 can be bead blasted to increase the adhesion of any material deposited thereon, thereby preventing flaking of material which results in contamination of the processing chamber 100. In one or more embodiments, the liner 112 includes one or more apertures 114 and a pumping channel 116 formed therein that is in fluid communication with a vacuum system. The apertures 114 provide a flow path for gases into the pumping channel 116, which provides an egress for the gases within the processing chamber 100.

The vacuum system can include a vacuum pump 118 and a throttle valve 120 to regulate flow of gases through the processing chamber 100. The vacuum pump 118 is coupled to a vacuum port 122 disposed on the chamber body 102 and therefore, in fluid communication with the pumping channel 116 formed in the liner 112. An aperture 124 aligns with the slit valve opening 108 disposed on a side wall of the chamber body 102 is formed within the liner 112 to allow entry and egress of substrates to/from the chamber body 102. The terms “gas” and “gases” are used interchangeably, unless otherwise noted, and refer to one or more precursors, reactants, catalysts, carrier, purge, cleaning, combinations thereof, as well as any other fluid introduced into the chamber body 102.

The apertures 114 allow the pumping channel 116 to be in fluid communication with a processing zone 126 within the chamber body 102. The processing zone 126 is defined by a lower surface of the lid assembly 104 and an upper surface of the pedestal 106, and is surrounded by the liner 112. The apertures 114 may be uniformly sized and evenly spaced about the liner 112. However, any number, position, size or shape of apertures may be used, and each of those design parameters can vary depending on the desired flow pattern of gas across the substrate receiving surface as is discussed in more detail below. In addition, the size, number and position of the apertures 114 are configured to achieve uniform flow of gases exiting the processing chamber 100. Further, the aperture size and location may be configured to provide rapid or high capacity pumping to facilitate a rapid exhaust of gas from the processing chamber 100. For example, the number and size of apertures 114 in close proximity to the vacuum port 122 may be smaller than the size of apertures 114 positioned farther away from the vacuum port 122.

In operation, one or more gases exiting the processing chamber 100 flow through the apertures 114 formed through the liner 112 into the pumping channel 116. The gas then flows within the pumping channel 116 and through ports into a vacuum channel and exits the vacuum channel through the vacuum port 122 into the vacuum pump 118.

Considering the lid assembly 104 in more detail, the lid assembly 104 includes a number of components stacked on top of one another, as shown in FIG. 1. In one or more embodiments, the lid assembly 104 includes a lid rim 128, a gas delivery assembly 130, and a top plate 132. The gas delivery assembly 130 is coupled to an upper surface of the lid rim 128 and is arranged to make minimum thermal contact therewith. The components of the lid assembly 104 are preferably constructed of a material having a high thermal conductivity and low thermal resistance, such as an aluminum alloy with a highly finished surface for example. Preferably, the thermal resistance of the components is less than about 5×10⁻⁴ m² K/W. The lid rim 128 is designed to hold the weight of the components making up the lid assembly 104 and is coupled to an upper surface of the chamber body 102 via a hinge assembly (not shown in this view) to provide access to the internal chamber components, such as the pedestal 106 for example.

The lid assembly 104 further includes an electrode 134 to generate a plasma of reactive species within the processing zone 126. In one embodiment, the electrode 134 is supported on the top plate 132 and is electrically isolated therefrom. For example, an isolator ring 136 is disposed about a lower portion of the electrode 134 separating the electrode 134 from the top plate 132. The isolator ring 136 can be made from aluminum oxide or any other insulative, process compatible material.

In one or more embodiments, the electrode 134 is coupled to a power source (not shown) while the gas delivery assembly 130 is connected to ground (i.e. the gas delivery assembly 130 serves as an electrode). Accordingly, a plasma of one or more process gases can be generated in the processing zone 126.

Any power source capable of activating the gases into reactive species and maintaining the plasma of reactive species may be used. For example, radio frequency (RF), direct current (DC), or microwave (MW) based power discharge techniques may be used. The activation may also be generated by a thermally based technique, a gas breakdown technique, a high intensity light source (e.g., UV energy), or exposure to an x-ray source. Alternatively, a remote activation source may be used, such as a remote plasma generator, to generate a plasma of reactive species which are then delivered into the processing chamber 100. While the processing chamber 100 is shown and described as a plasma processing chamber, the pedestal 106 as described herein may be utilized in other chambers that are not utilized for plasma processing, such as chemical vapor deposition (CVD) processes.

The pedestal 106 includes a cooling base 138. The cooling base 138 is coupled to a support member 140 and a flange 142 of a stem 144. The cooling base 138 includes a plurality of cooling channels 146 formed therein for flowing a coolant. The support member 140 includes a plurality of heating elements 148. The heating elements 148 function as a multi-zone heater.

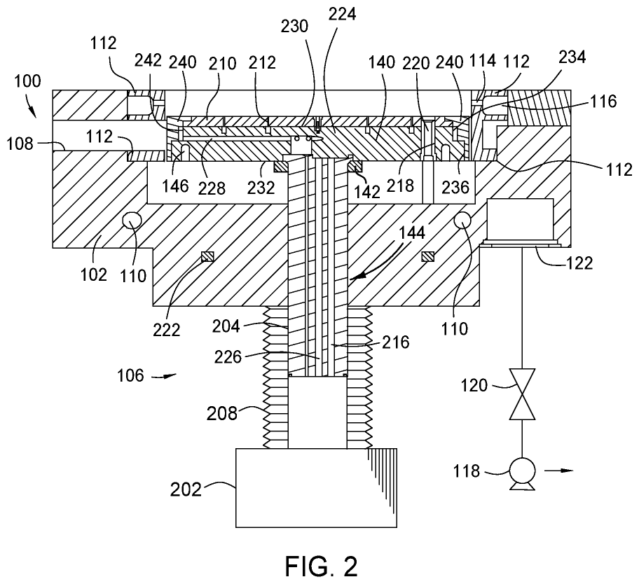

FIG. 2 shows a partial cross sectional view of an illustrative pedestal 106 in a portion of the processing chamber 100. The pedestal 106 can be at least partially disposed within the chamber body 102. The pedestal 106 includes the support member 140 to support a substrate (not shown in this view) for processing within the chamber body 102. The support member 140 is coupled to the cooling base 138 and the flange 142. The pedestal 106 is coupled to a lift mechanism 202 through a shaft 204 (the stem 144) which extends through a centrally-located opening 206 formed in a bottom surface of the chamber body 102. The lift mechanism 202 can be flexibly sealed to the chamber body 102 by a bellows 208 that prevents vacuum leakage from around the shaft 204. The lift mechanism 202 allows the pedestal 106 to be moved vertically within the chamber body 102 between a process position and a lower, transfer position. The transfer position is slightly below the opening of the slit valve opening 108 formed in a sidewall of the chamber body 102.

In one or more embodiments, the support member 140 has a flat, circular surface or a substantially flat, circular surface for supporting a substrate to be processed thereon. The support member 140 and the cooling base 138 are constructed of aluminum. The support member 140 can include a top plate 210 made of aluminum that may be coated with another material, such as silicon or ceramic material, for example, to reduce backside contamination of the substrate.

In one or more embodiments, the substrate (not shown) may be secured to the pedestal 106 using a vacuum chuck. The top plate 210 can include a plurality of holes 212 in fluid communication with the vacuum pump 118 via a vacuum conduit 216 disposed within the shaft 204 and the pedestal 106. Under certain conditions, the vacuum conduit 216 can be used to supply a purge gas to the surface of the support member 140 to prevent deposition when a substrate is not disposed on the support member 140. The vacuum conduit 216 can also pass a purge gas during processing to prevent a reactive gas or byproduct from contacting the backside of the substrate.

In one or more embodiments, the substrate (not shown) may be secured to the support member 140 using an electrostatic chuck. In one or more embodiments, the substrate can be held in place on the support member 140 by a mechanical clamp (not shown), such as a conventional clamp ring.

The pedestal 106 includes one or more bores 218 formed therethrough to accommodate a lift pin 220. Each lift pin 220 is typically constructed of ceramic or ceramic-containing materials, and are used for substrate-handling and transport. Each lift pin 220 is slidably mounted within the bore 218. In one aspect, the bore 218 is lined with a ceramic sleeve to help freely slide the lift pin 220. The lift pin 220 is movable within its respective bore 218 by engaging an annular lift ring 222 disposed within the chamber body 102. The lift ring 222 is movable such that the upper surface of the lift pin 220 can be located above the substrate support surface of the support member 140 when the lift ring 222 is in an upper position. Conversely, the upper surface of the lift pins 220 is located below the substrate support surface of the support member 140 when the lift ring 222 is in a lower position. Thus, part of each lift pin 220 passes through its respective bore 218 in the support member 140 when the lift ring 222 moves from either the lower position to the upper position.

When activated, the lift pins 220 push against a lower surface of the substrate, lifting the substrate off the support member 140. Conversely, the lift pins 220 may be de-activated to lower the substrate, thereby resting the substrate on the support member 140. The lift pins 220 can include enlarged upper ends or conical heads to prevent the lift pins 220 from falling out from the support member 140. Other pin designs can also be utilized and are well known to those skilled in the art.

In one embodiment, the pedestal 106 can include the support member 140 in the form of a substantially disk-shaped body 224. The shaft 204 has the vacuum conduit 216, a heat transfer fluid conduit 226 and a purge gas conduit 228. The disk-shaped body 224 comprises an upper surface 230, a lower surface 232 and a cylindrical outer surface 234. A thermocouple (not shown) is embedded in the disk-shaped body 224. A flange 236 extends radially outward from the cylindrical outer surface 234. The lower surface 232 comprise one side of the flange 236. A cooling channel 146 is formed in the disk-shaped body 224 proximate the flange 236 and lower surface 232. The cooling channel 146 is coupled to the heat transfer fluid conduit 226 of the shaft 204. A hole (not shown) is formed through the body 224 to couple the upper surface 230 to the vacuum conduit 216 of the shaft 204. The purge gas conduit 228 is formed through the disk-shaped body 224 and exits the cylindrical outer surface 234 of the body 224. The purge gas conduit 228 has an orientation substantially perpendicular to a centerline of the disk-shaped body 224.

Referring again to FIG. 2, the pedestal 106 can include an edge ring 240 disposed about the support member 140. The edge ring 240 can be made of a variety of materials such as ceramic, quartz, aluminum and steel, among others. In one or more embodiments, the edge ring 240 is an annular member that is adapted to cover an outer perimeter of the support member 140 and protect the support member 140 from deposition. The edge ring 240 can be positioned on or adjacent the support member 140 to form an annular purge gas channel 242 between the outer diameter of support member 140 and the inner diameter of the edge ring 240. The annular purge gas channel 242 can be in fluid communication with the purge gas conduit 228 formed through the support member 140 and the shaft 204. The purge gas conduit 228 is in fluid communication with a purge gas supply (not shown) to provide a purge gas to the purge gas channel 242. Any suitable purge gas such as nitrogen, argon, or helium, may be used alone or in combination. In operation, the purge gas flows through the purge gas conduit 228, into the purge gas channel 242, and about the substrate disposed on the support member 140. Accordingly, the purge gas working in cooperation with the edge ring 240 prevents deposition at the edge and/or backside of the substrate.

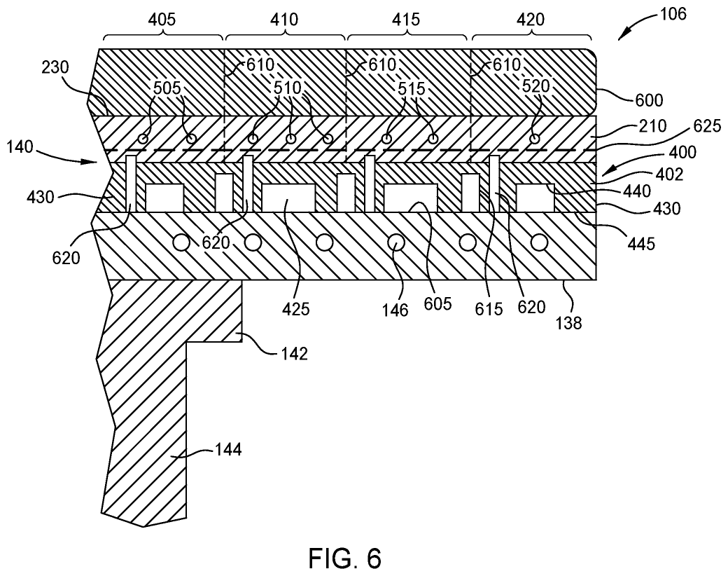

The temperature of the pedestal 106 is controlled by a fluid circulated through the cooling channel 146 embedded in the body of the pedestal 106. The cooling channel 146 and heat transfer fluid conduit 226 can flow heat transfer fluids to either heat or cool the pedestal 106. Any suitable heat transfer fluid may be used, such as water, nitrogen, ethylene glycol, or mixtures thereof. The pedestal 106 can further include an embedded temperature sensor (shown in FIG. 6) for monitoring the temperature of the support surface of the support member 140. For example, a signal from the thermocouple may be used in a feedback loop to control the temperature or flowrate of the fluid circulated through the cooling channel 146.

The pedestal 106 can be moved vertically within the chamber body 102 so that a distance between pedestal 106 and the lid assembly 104 can be controlled. A sensor (not shown) can provide information concerning the position of pedestal 106 within processing chamber 100.

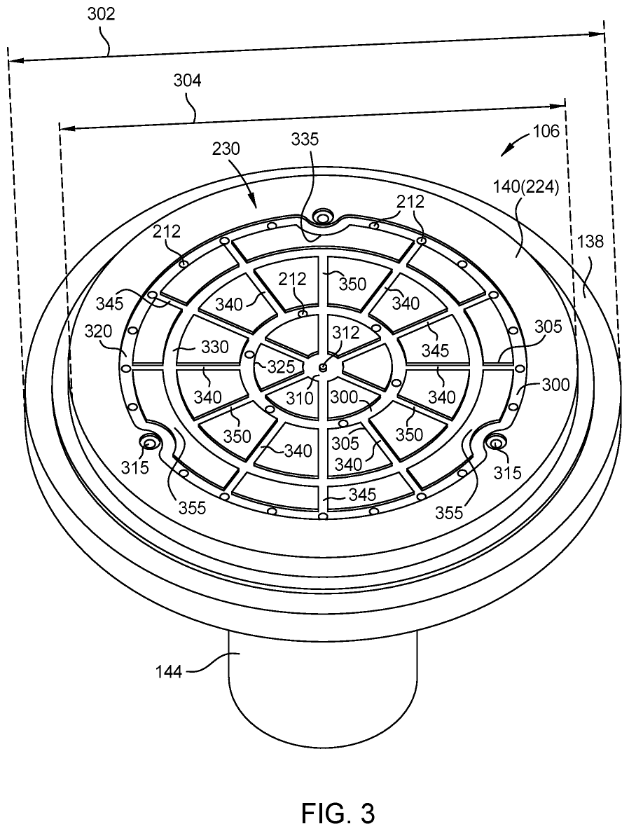

FIG. 3 is an isometric top view of the pedestal 106 as disclosed herein. The pedestal 106 includes the support member 140 coupled to the cooling base 138. The cooling base 138 has a diameter 302 greater than a diameter 304 of the support member 140. The support member 140 includes a plurality of circular grooves 300 formed in the upper surface 230. The circular grooves 300 are connected to radial grooves 305. The radial grooves 305 terminate at a central depression 310 formed in the upper surface 230. Each of the circular grooves 300, the radial grooves 305, and the central depression 310 are recessed slightly from a plane of the upper surface 230.

The plurality of holes 212 are shown in in a base of a portion of the plurality of circular grooves 300. The holes 212 are provided in the circular grooves 300 and the radial grooves 305. The holes 212 may be utilized for vacuum application or purge gas application to a substrate (not shown). The central depression 310 includes a protrusion 312 that may be utilized for substrate centering. Openings 315 are also shown on the pedestal 106. The openings 315 are positioned outside of a perimeter of the outermost circular groove 300. The openings 315 are utilized for the lift pins 220 (one is shown in FIG. 2).

In one embodiment, the plurality of circular grooves 300 includes an outer groove 320, an inner groove 325 adjacent to the central depression 310, and an intermediate groove 330 positioned between the outer groove 320 and the inner groove 325. The plurality of holes 212 are formed in one or both of the outer groove 320 and the inner groove 325. The outer groove 320 includes a plurality of inwardly extending arc segments 335. Each of the inwardly extending arc segments 335 accommodates one of the openings 315.

In some embodiments, the radial grooves 305 include a plurality of first linear grooves 340, a plurality second linear grooves 345 and a plurality of third linear grooves 350. The first linear grooves 340 alternate with the third linear grooves 350. Each of the plurality second linear grooves 345 are positioned 180 degrees from each of the plurality of third linear grooves 350. The first linear grooves 340 are 180 degrees from each other. The plurality of first linear grooves 340 extend between the outer groove 320 and the inner groove 325. The plurality second linear grooves 345 extend between the outer groove 320 and the central depression 310. The plurality of third linear grooves 350 extend between the intermediate groove 330 and the central depression 310. An area 355 between the intermediate groove 330 adjacent to the inwardly extending arc segments 335 does not include a linear groove. Thus, the area 355 is a portion of the upper surface 230 (in the same plane as the plane of the upper surface 230).

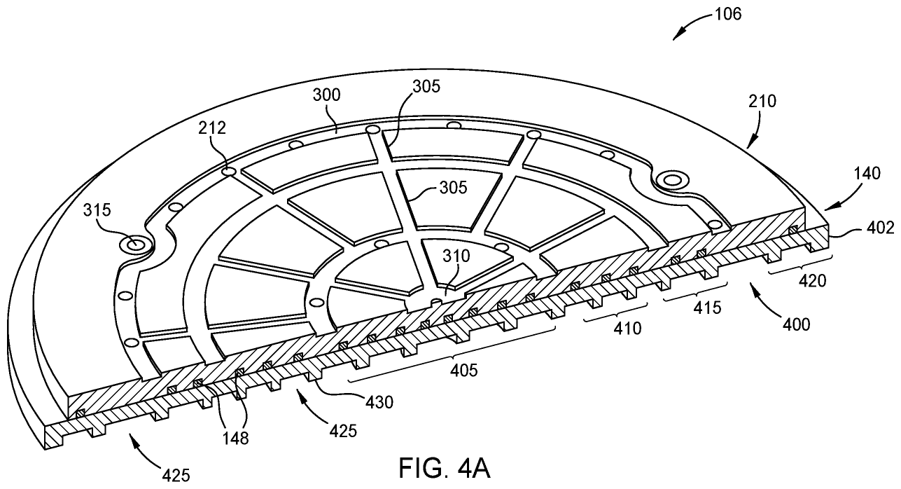

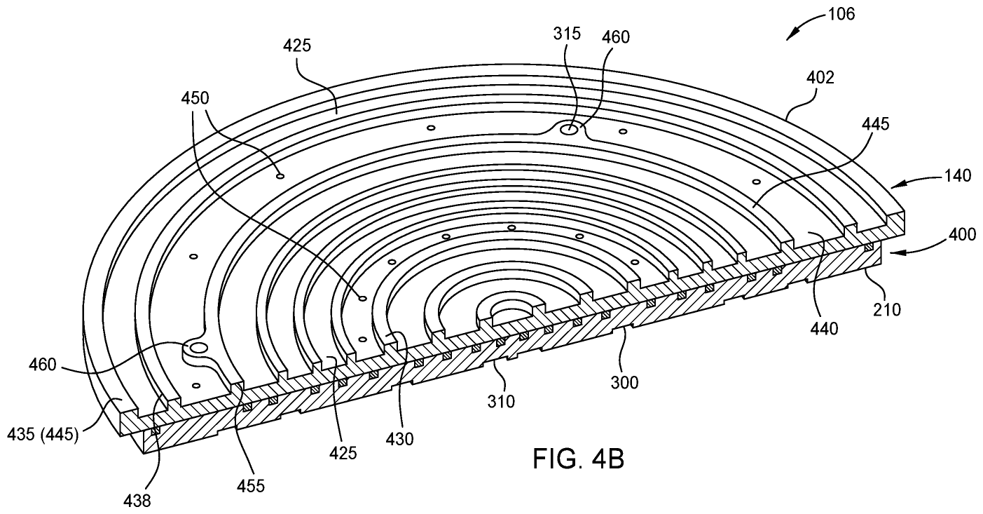

FIGS. 4A and 4B are isometric sectional views of the pedestal 106 of FIG. 3. FIG. 4A is a top sectional view and FIG. 4B is a bottom sectional view.

The pedestal 106 includes a multi-zone heater 400 adapted to control the temperature of a substrate being processed thereon. The multi-zone heater 400 includes the heating elements 148 separated into four independently controllable radial zones, shown as a central or first zone 405, a second zone 410, a third zone 415 and an outer or fourth zone 420. The multi-zone heater 400 is formed in or on the top plate 210. The top plate 210 is coupled to a base plate 402 that couples directly to the cooling base 138 (not shown).

The base plate 402 also includes a plurality of grooves 425 separated by ridges 430. The grooves 425 and the ridges 430 are more clearly shown in FIG. 4B. The grooves 425 and the ridges 430 are generally axially positioned and/or concentric across a lower surface 435 of the base plate 402.

The ridges 430 are adapted to contact the cooling base 138 and the grooves 425 are at least partially bounded by sidewalls 438 of the ridges 430 when the cooling base 138 is coupled to the base plate 402. Each of the grooves 425 include one or more surfaces 440 that are adapted to be in thermal contact with a fluid flowed in the grooves 425 between the sidewalls 438 of the ridges 430, and the cooling base 138.

In one embodiment, a surface area of the grooves 425 (e.g., the surfaces 440, collectively) is about 70 square inches to about 80 square inches. In another embodiment, contact surfaces 445 of the ridges 430 (the surface area of the ridges 430 between the sidewalls 438) have a collective surface area of about 40 square inches to about 50 square inches.

An intermediate ridge 455 of the ridges 430, corresponding to the position of the openings 315, includes a plurality of arc-shaped contact surfaces 460 surrounding each of the openings 315.

The base plate 402 also includes a plurality of openings 450 in a portion of the grooves 425. The openings 450 are utilized to flow a gas to the holes 212 in the top plate 210 (shown in FIG. 4A). For example, a gas can be flowed to one or more of the grooves 425 to assist in cooling the pedestal 106, and the gas is exhausted through the openings 450 and the holes 212 to the backside of a substrate (not shown) positioned on the top plate 210.

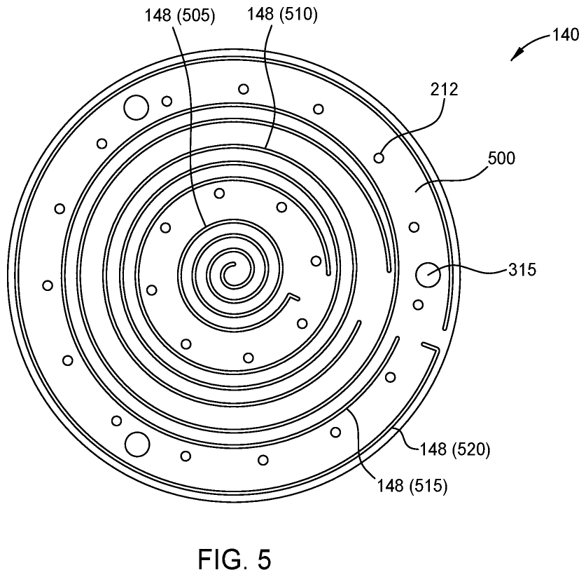

FIG. 5 is a schematic view of a bottom surface 500 of the support member 140 of the pedestal 106 of FIG. 3. Also shown are the heating elements 148 provided in or on the bottom surface 500 of the support member 140. The heating elements 148 include a first or central heater element 505 (corresponding to the first zone 405), a second heater element 510 (corresponding to the second zone 410), a third heater element 515 (corresponding to the third zone 415) and an outer or fourth heater element 520 (corresponding to the fourth zone 420).

FIG. 6 is a partial sectional view of the pedestal 106 with a portion of a substrate 600 positioned thereon. When the support member 140 is coupled to the cooling base 138, contact surfaces 445 of the ridges 430 of the base plate 402 are in thermal communication with a surface 605 of the cooling base 138. During operation, a coolant is flowed in the cooling channels 146 of the base plate 402, and the contact surfaces 445 of the ridges 430 of the base plate 402 are utilized to control the temperature of the substrate 600. Additionally, the multi-zone heater 400 is utilized to control the temperature of the substrate 600 positioned on the support member 140. The upper surface 230 will contact the substrate 600 in the four zones 405-420. For example, independent temperature control is provided by the heating elements 148 in each of the zones 405-420. Further temperature control of the support member 140 and/or the substrate 600 is provided by flowing a fluid through the grooves 425 formed in the base plate 402. The fluid may be an inert gas. The fluid is circulated in the grooves 425 or exhausted through the holes 212 in the support member 140 as a backside gas. The multi-zone heater 400 operates in conjunction with the fluid flowed in both of the grooves 425 and the cooling channels 146 in order to control the temperature of the substrate 600 in the various zones. For example, temperatures in any of the zones 405-420 may be the same or different. The pedestal 106 as described herein is an actively zone-controlled heater that is powered based on each zone's temperature measurement.

In one embodiment, thermal breaks 610 are provided between the zones 405-420. Each of the thermal breaks 610 may be an intermediate groove 615 similar to the grooves 425. Each intermediate groove 615 is positioned between adjacent zones 405-420.

The pedestal 106 also includes temperature sensors 620 provided in each of the zones 405-420. Each of the temperature sensors 620 may be thermocouples. Each of the temperature sensors 620 extend through the base plate 402 and the top plate 210 to a thermal interface 625 (shown as a dashed line) in the top plate 210. The temperature sensors 620 touch the thermal interface 625 in each of the zones 405-420 and provide temperature measurements in each zone 405-420. The temperature sensors 620 provide feedback to enable control of power applied to the multi-zone heater 400, and thus enhance temperature control of the pedestal 106.

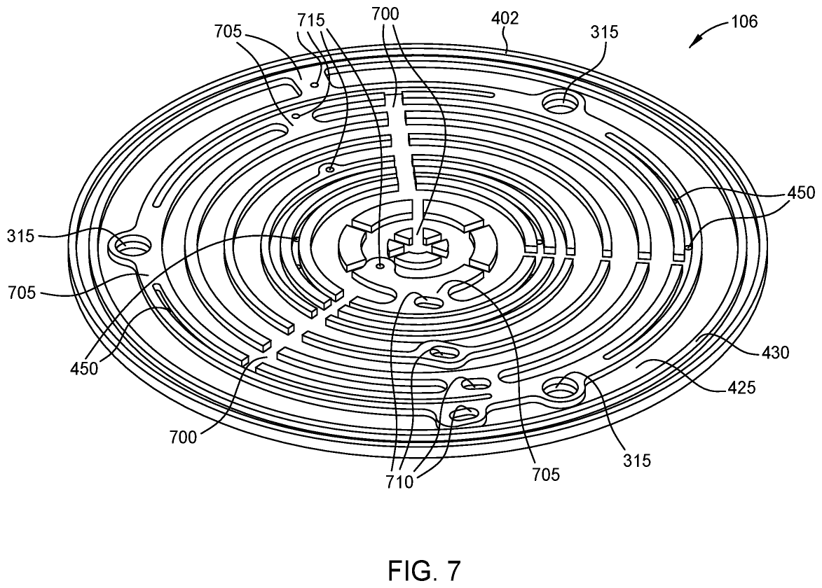

FIG. 7 is a bottom perspective view of the pedestal 106 showing another embodiment of the base plate 402. The base plate 402 shown in FIG. 7 can be used with the top plate 210 of FIGS. 2 and 3.

The base plate 402 includes the plurality of grooves 425 separated by ridges 430 similar to the base plate 402 of FIG. 4B. However, a portion of the ridges 430 are separated by radial grooves 700. The radial grooves 700 connect a portion of the grooves 425. The radial grooves 700 also assist in delivering the fluid flowed in the grooves 425 to the holes 212 in the top plate 210 (shown in FIG. 4A) via the openings 450.

The base plate 402 also includes a plurality of interface portions 705. The interface portions 705 are regions where the ridges 430 are widened and/or where adjacent ridges 430 are connected. The base plate 402 also includes a plurality of heater connection ports 710. The heater connection ports 710 are formed in the interface portions 705 of the ridges 430. The heater connection ports 710 are utilized to connect wires or leads to the multi-zone heater 400.

The base plate 402 also includes a plurality of temperature control ports 715. Each of the temperature control ports 715 are utilized to receive a temperature sensor 620 (shown in FIG. 6).

While the foregoing is directed to embodiments of the present disclosure, other and further embodiments of the disclosure may be devised without departing from the basic scope thereof, and the scope thereof is determined by the claims that follow.

What is claimed is:

1. A pedestal, comprising:
a top plate; and
a base plate coupled to the top plate, wherein the base plate comprises a plurality of grooves formed in a bottom surface thereof; and the top plate comprises:
a multi-zone heater;
a plurality of circular grooves; and
a plurality of linear grooves intersecting with a portion of the circular grooves, wherein a portion of the linear grooves intersect with a depression formed in a center of the top plate.

2. The pedestal of claim 1, further comprising:
a cooling base coupled to the base plate, the cooling base including a plurality of cooling channels.

3. The pedestal of claim 2, further comprising:
a shaft coupled to the cooling base.

4. The pedestal of claim 1, wherein the grooves have a collective surface area of about 70 square inches to about 80 square inches.

5. The pedestal of claim 1, further comprising:
a plurality of ridges formed on the bottom surface, wherein one of the plurality of ridges separates adjacent grooves.

6. The pedestal of claim 5, wherein the grooves have a collective surface area of 70 square inches to about 80 square inches.

7. The pedestal of claim 6, wherein the ridges have a collective surface area of about 40 square inches to about 50 square inches.

8. The pedestal of claim 1, wherein the grooves are adapted for flowing a gas therein.

9. The pedestal of claim 8, wherein the gas is exhausted through holes formed in the top plate.

10. A pedestal, comprising:
a top plate comprising:
a four zone heater;
a plurality of circular grooves; and
a plurality of linear grooves intersecting with a portion of the circular grooves, the pedestal further comprising:
a base plate coupled to the top plate; and
a cooling plate coupled to the base plate, wherein the base plate comprises a plurality of grooves formed in a surface that is in contact with the cooling base.

11. The pedestal of claim 10, wherein the grooves have a collective surface area of about 70 square inches to about 80 square inches.

12. The pedestal of claim 10, further comprising:
a plurality of ridges formed on the surface of the base plate, wherein one of the plurality of ridges separates adjacent grooves.

13. The pedestal of claim 12, wherein the grooves have a collective surface area of 70 square inches to about 80 square inches.

14. The pedestal of claim 13, wherein the ridges have a collective surface area of about 40 square inches to about 50 square inches.

15. The pedestal of claim 10, wherein the grooves are at least partially bounded by a surface of the cooling plate and are adapted for flowing a gas therein.

16. The pedestal of claim 15, wherein the gas is exhausted through holes formed in the top plate.

17. A pedestal, comprising:
a top plate;
a base plate coupled to the top plate, wherein the base plate comprises a plurality of grooves formed in a bottom surface thereof; and the top plate further comprises:
a multi-zone heater forming one or more heating zones;
a plurality of circular grooves; and
a plurality of linear grooves intersecting with a portion of the circular grooves, wherein the pedestal further comprises:
a cooling plate coupled to the base plate, wherein the base plate comprises a plurality of grooves formed in a surface that is in contact with the cooling base, and a thermal break is positioned between adjacent heating zones.

18. The pedestal of claim 17, further comprising:
a plurality of ridges formed on the surface of the base plate, wherein one of the plurality of ridges separates adjacent grooves.

19. The pedestal of claim 18, wherein the grooves have a collective surface area of 70 square inches to about 80 square inches.

20. The pedestal of claim 18, wherein the ridges have a collective surface area of about 40 square inches to about 50 square inches.
